(19) United States
(12) Patent Application Publication
(10) Pub. No.: US 2019/0244784 A1
(43) Pub. Date: Aug. 8, 2019

(54) METHOD OF PROCESSING A SURFACE BY MEANS OF A PARTICLE BEAM

(71) Applicant: SCIA SYSTEMS GMBH, Chemnitz (DE)

(72) Inventors: Thoralf Dunger, Chemnitz (DE); Marcel Demmler, Wilkau-Haßlau (DE); Michael Zeuner, Chemnitz (DE); Matthias Nestler, Nossen (DE)

(73) Assignee: SCIA SYSTEMS GMBH, Chemnitz (DE)

(21) Appl. No.: 16/340,363

(22) PCT Filed: Oct. 12, 2017
(86) PCT No.: PCT/EP2017/076047

§ 371 Date: Apr. 8, 2019

(30) Foreign Application Priority Data
Oct. 12, 2016 (DE) 10 2016 119 437.9

(51) Int. Cl. H01J 37/304; H01J 37/305

(52) U.S. Cl. CPC H01J 37/3045; H01J 2237/3151; H01J 2237/30466; H01J 37/3056

(57) ABSTRACT

A method for processing a surface, having an initial topology, using a particle beam can include processing of the surface using the particle beam at a first angle of the particle beam with respect to the surface in accordance with a target topology of the surface. The method can furthermore include subsequent processing of the surface using the particle beam at a second angle of the particle beam with respect to the surface in accordance with the target topology of the surface, wherein the second angle differs from the first angle.

Various embodiments relate to methods for processing a surface by means of a particle beam.

A particle beam, such as an ion beam or an electron beam, can be used to precisely modify a surface, or the topology thereof. A particle-beam-supported method can be used, for example, to process the surface of an optical structural element or the surface of an electronic structural element, for example a chip or a precursor of a chip in chip production.

Surfaces to be processed are generally characterized in that they have areas having unevennesses that are to be processed, for example removed, or structures with sizes on different size scales. The smaller the area of incidence of a particle beam on a surface is, the higher is the spatial resolution with which the surface can be processed and the smaller are the unevennesses or structures that can be successfully processed.

Therefore, in a conventional particle-beam-supported method, a comparatively small area of incidence is used, for example having a corresponding, comparatively small diameter, so as to be able to process both comparatively small structures and comparatively large structures in one operation. Consequently, however, areas of the surface that have, for example, only unevennesses or structures to be processed on a comparatively large size scale are processed with a comparatively unnecessarily small area of incidence. This influences the duration of the method, which constitutes a corresponding cost factor, because the smaller the area of incidence is, the longer it may take to scan the entire surface with the particle beam. A long process duration may also increase the risk of damage to the surface that is to be processed, because a particle beam may cause electrostatic breakdowns and/or flashovers and locally high temperatures.

DE 10 2012 022 168 A1 discloses a method for producing a planar surface on a material piece. In accordance with the method, a substantially planar first surface region of the material piece is removed by removing a first material volume from the material piece by particle beam etching using a particle beam, wherein an angle between the beam axis of the particle beam column and the first surface region is smaller than 10°. Furthermore, in accordance with the method, a substantially planar second surface region is produced by removing a second material volume from the material piece by particle beam etching using an ion beam, wherein an angle between the beam axis and the second surface region is greater than 30°.

A. Schindler et al., Ion Beam and Plasma Jet Etching for Optical Component Fabrication, Lithographic and Micromachining Techniques for Optical Component Fabrication, Proceedings of SPIE Vol. 4440, pages 217 to 227, 2001, describe various techniques and fields of use of ion beam etching.

H. Takino et al., Ultraprecision Machining of Optical Surfaces, URL: http://www.jspe.or.jp/wp_e/wp-content/uploads/isupen/2011s/2011s-1-2.pdf, describe the ion beam processing of a complexly shaped optical component.

EP 1 680 800 B1 describes a method and an apparatus for ion beam processing surfaces, wherein the characteristic of the ion beam is changed by changing the ion acceleration, the ion energy distribution, the ion current density, the ion density distribution, and/or by pulsing the ion beam.

In various embodiments, a method can be illustratively provided in which a surface is processed several times (that is to say at least twice) using a particle beam, wherein the particle beam acts on the surface in an area of incidence (for example etching/material removal). For each processing operation, the particle beam can be guided across the surface at a respectively different angle between the particle beam and the surface. Due to the different angles, for example the geometric shape and size of the area of incidence of the particle beam on the surface is, however, different for each processing operation, as a result of which in each case a different spatial resolution of the respective processing operation is obtained. It is thus possible for, for example, unevennesses or structures of the surface on different size scales to be processed by processing the surface several times with different spatial resolutions (which are adapted to the different size scales). Hereby, for example the process duration, the resource consumption (for example water for cooling, gas for generating particle beams, and energy for the operation of an apparatus) and the risk of damage to the surface or damage to the substrate associated with the surface can be reduced.

A method for processing a surface having an initial topology using a particle beam may include processing of the surface using the particle beam at a first angle of the particle beam with respect to the surface in accordance with a target topology of the surface. The method may furthermore include subsequent processing of the surface using the particle beam at a second angle of the particle beam with respect to the surface in accordance with the target topology of the surface, wherein the second angle differs from the first angle.

Optionally, only the angle of the particle beam with respect to the surface may be changed, wherein further parameters of the particle beam, of the particle beam characteristic, and/or of the particle beam generation are kept substantially constant or only have deviations below a tolerance value.

A further method for processing a surface having an initial topology using a particle beam may include processing of the surface using the particle beam, wherein the particle beam is incident on the surface at a first angle with respect to the surface in accordance with a target topology of the surface. The method may furthermore include simulating the topology of the surface after processing at the first angle. In addition, the method may include subsequent processing starting from the simulated topology of the surface using the particle beam, wherein the particle beam is incident on the surface at a second angle with respect to the surface in accordance with a target topology of the surface, wherein the second angle differs from the first angle.

Optionally, only the angle of the particle beam with respect to the surface may be changed, wherein further parameters of the particle beam, of the particle beam characteristic, and/or of the particle beam generation are kept substantially constant or only have deviations below a tolerance value.

In a particle-beam-supported method it is possible to ascertain how much material should be removed locally from a surface to obtain, starting from an initial topology of the surface, a desired target topology of the surface. For example, a plan of procedure/movement profile for a particle beam can be established/ascertained based on the difference between an initial topology of the surface and a desired target topology of the surface. For example, the particle beam or the area of incidence of the particle beam on the surface can scan the surface based on the plan of procedure. Such a plan of procedure/movement profile can include for example that the particle beam or the area of incidence of the particle beam is guided across the surface with varying speeds and/or different intensities of the particle beam, with the result that locally varying removal rates of material are obtained in different areas of the surface.

For example, the particle beam or the area of incidence of the particle beam may be moved with a comparatively low speed over areas of the surface in which locally comparatively large amounts of material are to be removed, and may be moved with a comparatively high speed over areas of the surface in which comparatively little material is to be removed.

Unevennesses or structures to be processed of a surface of a body, for example of a substrate (for example of a wafer or of a lens), for example in a size scale in the millimetre range, can successfully be processed, for example, only with a particle beam which has a size of the area of incidence (i.e., a corresponding spatial resolution) of the particle beam that corresponds to the size scale. For example, the area of incidence can require a diameter that is likewise at the size scale in the millimetre range or less in order to be able to process the unevennesses or structures successfully, for example to flatten them.

A method may include processing the surface at least twice, wherein in each case mutually differing angles and consequently mutually different sizes of the areas of incidence and spatial resolutions can be set. It is possible to establish/ascertain a plan of procedure/movement profile with a different spatial resolution for each processing operation. Due to the fact that such a method can be performed, for example including processing with a comparatively great spatial resolution and subsequent processing with a comparatively small spatial resolution, unevennesses or structures to be processed of the surface can be processed with spatial resolutions that are adapted substantially or at least partially to a respective size scale of the unevennesses or structures. For example, the (total) method duration and the risk of damage to the surface or to a substrate having a surface that is processed using the particle beam can thus be decreased.

In accordance with various embodiments, a surface can be processed more than twice. For example, the surface can be processed three times, four times or even more frequently with respectively different angles. This may also include, for example, performing a corresponding simulation for each processing operation, ascertaining/setting an angle of the particle beam relative to the surface to be processed, and/or establishing a plan of procedure.

In accordance with various embodiments, simulating the topology of the surface can be performed before and/or during the processing operation at the first angle.

A computer simulation/calculation can take several minutes, depending on the circumstances such as the computation speed of the processor or the topology of the surface to be processed. By simulating the topology of the surface before and/or during the first processing operation, the (total) method duration can be decreased.

In accordance with various embodiments, the method may further include simulating successively performed processing operations on the surface with the particle beam at respectively different angles of the particle beam with respect to the surface, wherein at least one simulation can be used to ascertain at least the respectively different angles for the successively performed processing.

A simulation/calculation, for example using a processor, can utilize one or more mathematically analytical calculation methods and/or numerical calculation methods. A simulation/calculation of several processing operations can be divided such that a part of the simulation/calculation is performed during and/or before different processing processes, for example during a first processing operation, for example to decrease the (total) method duration.

A simulation/calculation can also include a plurality of partial simulations/calculations. For example, a partial simulation can be performed for each processing of the surface, wherein a result of a preceding simulation can be used as the basis or a parameter for a subsequent simulation.

By way of a simulation/calculation, it is also possible to ascertain the mutually different areas of incidence of the particle beam and consequently the mutually different angles of the particle beam with respect to the surface and consequently the different spatial resolutions that are provided for (successfully) processing the surface. For example, the mutually different angles and areas of incidence can be ascertained such that the total method duration is minimized and/or that the risk of damage to the surface or to the substrate associated with the surface is decreased or optimized.

In accordance with various embodiments, the first angle and/or the second angle of the particle beam with respect to the surface may be infinitely settable.

Due to the infinite setting, the first angle and the second angle and consequently the respective area of incidence can be set precisely for a respective processing of a topology or of part of a topology. Further angle settings can also be performed infinitely.

In accordance with various embodiments, the current density and/or the current flow (that is to say the number of particles per unit time) of the particle beam during the different processing operations of the surface can be substantially the same.

For example, further parameters, for example parameters of particle beam generation such as an acceleration voltage, or a particle current density distribution during one or more processing operations, can be substantially the same, for example constant or having deviations only below a tolerance value.

Changing parameters of the particle beam, of the particle beam characteristic, and/or of the particle beam generation can have the result that, for example, a particle beam source and, as a result, the particle beam can require a time interval until the particle beam has a substantially constant beam characteristic. For example, until a particle beam source emits a particle beam with a substantially constant particle beam characteristic, several minutes may pass after one or more parameters is/are changed. Within this time interval, processing of a surface may not be possible or be possible to a reduced extent because, for example, the removal rate of material from the surface can vary within this time interval. The total method duration can be decreased by keeping parameters substantially the same, for example constant or only having deviations below a tolerance value, and varying for example only the angle between the particle beam and the surface.

According to various embodiments, the first angle and/or the second angle of the particle beam with respect to the surface can be set by way of positioning the particle beam and/or by way of positioning the surface.

For example, a particle beam source and/or the surface, or a substrate associated with the surface, can be provided with holders that make possible and/or facilitate the positioning and/or the setting of the angle between particle beam and surface.

In accordance with various embodiments, an instantaneous topology of the surface can be measured only before and/or after the two processing operations of the surface.

In conventional methods, the topology of the surface before and after each processing operation is measured to ascertain the initial topology and also the success of the method.

Due to the fact that, in accordance with various embodiments, a simulation of processing operations carried out several times is performed, wherein for example (simulated) results of a preceding processing operation can be used as a parameter or the basis for simulating a subsequent processing operation, a topology can be measured only before and/or after all processing operations of the surface.

Measuring can mean for example that the surface, or an associated substrate, must be removed from an apparatus, which can increase the total method duration and entails a risk of contamination of or damage to the surface.

In accordance with various embodiments, the surface can be processed in a chamber having a pressure which is lower than the air pressure, and the chamber can be vented and/or opened only before and after both processing operations of the surface.

Due to the fact that the chamber is not opened, the total method duration and a risk of contamination of or damage to the surface can likewise be decreased.

In accordance with various embodiments, the method can furthermore include regulating and/or controlling the temperature of the surface in dependence on the angle of the particle beam with respect to the surface.

At different angles of the particle beam with respect to the surface, and consequently different shapes of the area of incidence, the particle densities (or density distributions) that are incident on the different areas of incidence can differ and thus act differently on the surface, for example etching/removal of material. Accordingly, a respective other temperature development can also be present. By way of controlling and/or regulating the temperature of the surface, or of the associated substrate, that has been adapted to the respective angle, the risk of damage can be decreased due to a temperature development during the processing.

Furthermore, for example other parameters of a particle beam apparatus, such as for example the degree of particle beam neutralization in the case of charged particles such as ions or electrons, can also be adapted to the respective angle.

In accordance with various embodiments, the method may further include simulating successively performed processing operations on the surface with the particle beam, wherein at least one simulation can be used to ascertain the method duration of the successively performed processing. Furthermore, the method may include adapting a threshold value of the difference between a target topology and an initial topology if the ascertained method duration exceeds a threshold value.

For example, if a desired method duration exceeds a threshold value, for example takes too long, the precision of the processing can be adapted to attain the desired method duration. Due to the fact that the multiple processing operations are simulated first, for example the (total) method duration, the precision of the processing, the resource consumption (for example energy, water and/or gas) and/or the schedule of a plurality of successive methods can be adapted and designed dynamically.

In accordance with various embodiments, simulating one or more processing operations of the surface may include a Fourier analysis.

For example, the difference between the initial topology and the target topology of the surface may be converted into a surface waviness by way of a Fourier transform. The surface waviness may be a variable for a simulation or for calculation methods of a simulation with which calculation using a processor may be accelerated.

The surface waviness (also referred to as local waviness) can be used for the division into a plurality of processing operations. For example, one spatial resolution can be used to process comparatively high frequencies of the surface waviness, and another spatial resolution can be used to process comparatively low frequencies of the surface waviness.

In accordance with various embodiments, it is possible in the case of a simulation of one or multiple processing operations of the surface using the particle beam, to ascertain the (at least estimated) method duration and/or processing duration.

In accordance with various embodiments, the simulation of at least one processing operation can include filtering, which means that the simulation can be based on an adapted model of the topology of the surface.

Filtering, for example mathematical filtering with a filter function, which can be performed by a processor, can be effected such that it is performed before and/or with a simulation, for example as part of a simulation. Simulating one or multiple processing operations can take several minutes, depending on the topology of the surface to be processed. Using filtering, the mathematical model of the topology can be changed such that simulating may require less time.

For example, the model of the surface may be adapted by way of filtering such that unevennesses or structures of the surface, which have for example such a size scale that they cannot be processed using the particle beam, are “masked out” owing to the filtering. Consequently, for the simulation for example no time or less time can be spent to include unevennesses or structures of the surface in a calculation that are for example not processable in principle.

Embodiments are explained in more detail below and are represented in the figures,

in which

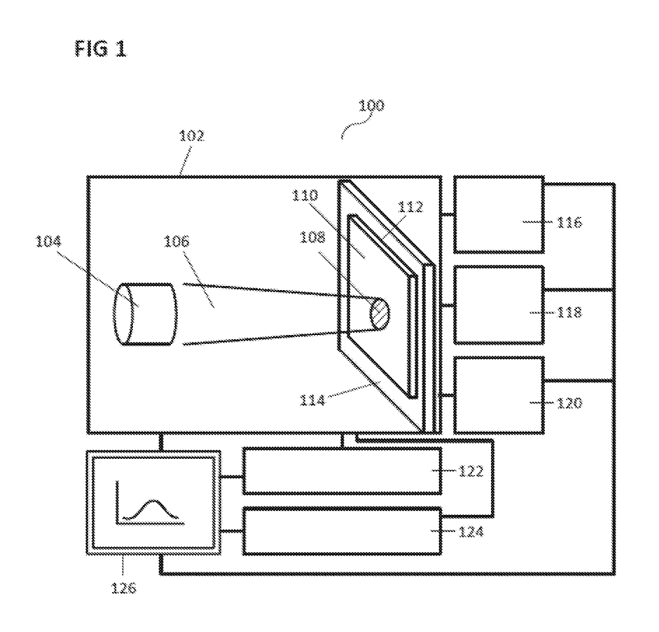

FIG. 1 shows an arrangement for a method for processing a surface using a particle beam;

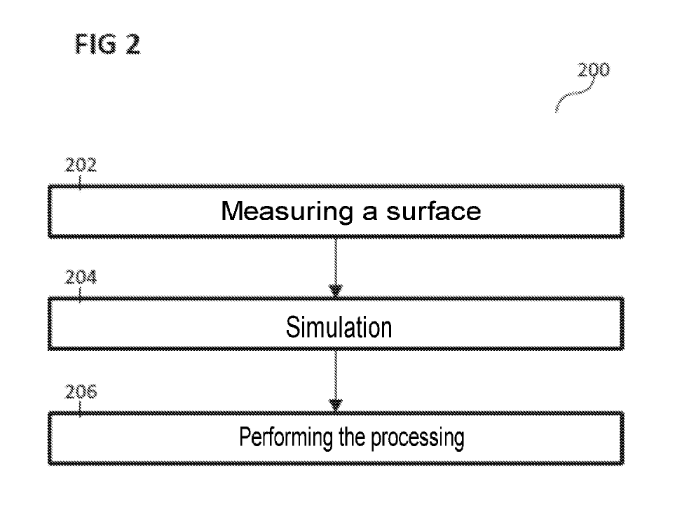

FIG. 2 shows an embodiment of a method for processing a surface using a particle beam;

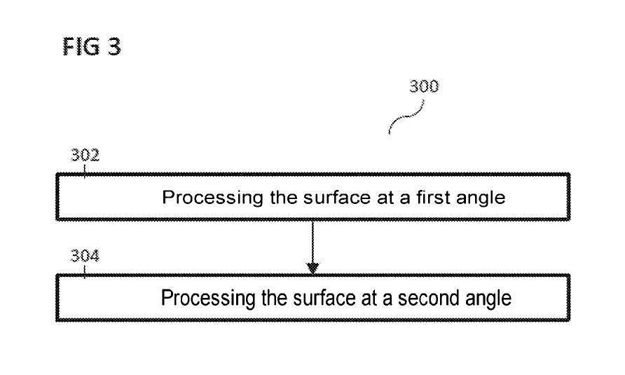

FIG. 3 shows a further embodiment of a method for processing a surface using a particle beam;

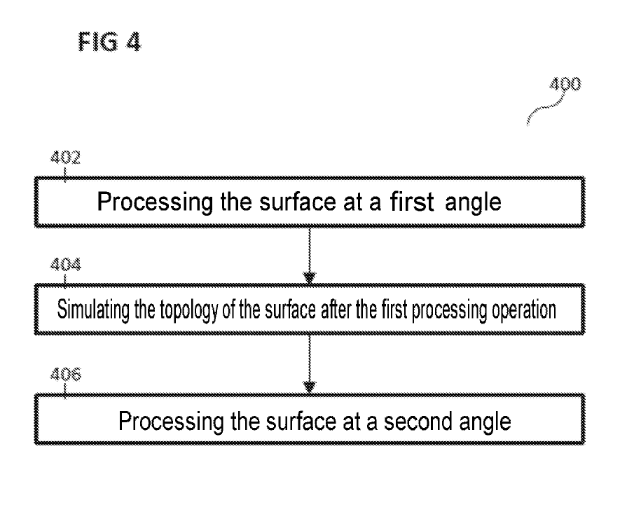

FIG. 4 shows a further embodiment of a method for processing a surface using a particle beam;

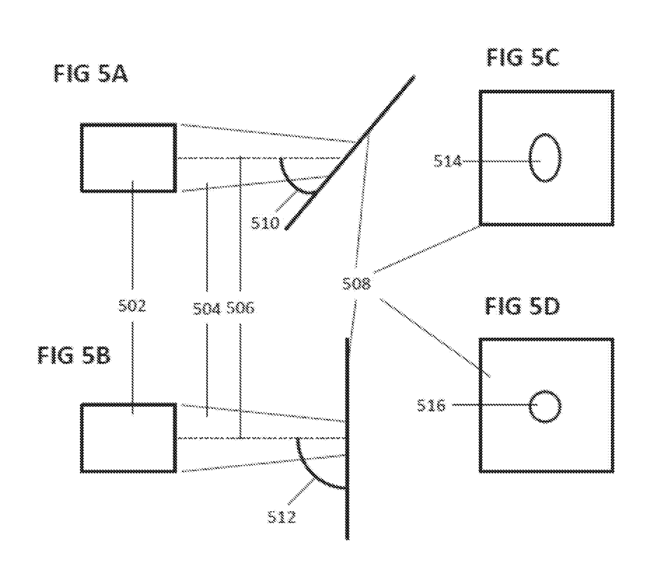

FIGS. 5A, 5B, 5C and 5D each shows an embodiment for processing a surface at a respective angle; and

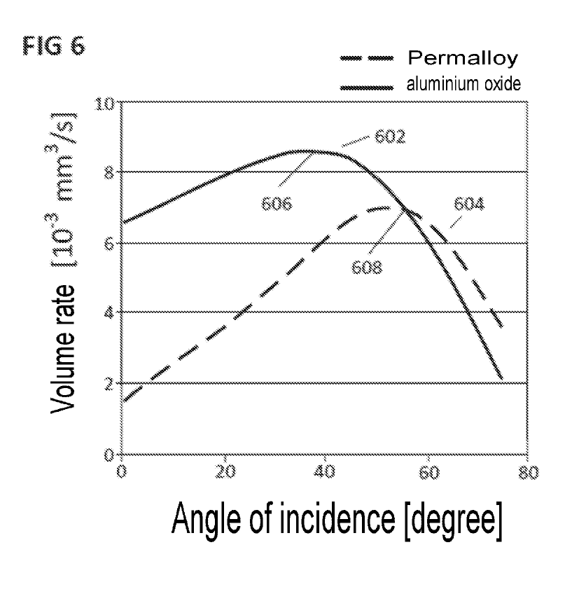

FIG. 6 shows a diagram of the volume removal rate as a function of the angle of incidence for two different materials.

In the following detailed description, reference is made to the accompanying drawings, which form part of this description and in which specific embodiments in which the invention can be carried out are shown for purposes of illustration. In this respect, directional terminology such as for instance “at the top”, “at the bottom”, “at the front”, “at the rear”, “front”, “rear”, etc. is used with reference to the orientation of the figure(s) described. Since components of embodiments may be positioned in a number of different orientations, the directional terminology serves for purposes of illustration and is in no way restrictive. It goes without saying that other embodiments may be used and structural or logical changes made without departing from the scope of protection of the present invention. It goes without saying that the features of the various embodiments described herein by way of example can be combined with one another, unless otherwise specifically stated. The following detailed description is therefore not to be interpreted in a restrictive sense, and the scope of protection of the present invention is defined by the appended claims.

In the course of this description, the terms “connected” and “coupled” are used for describing both a direct connection and an indirect connection and both a direct coupling and an indirect coupling. In the figures, identical or similar elements are provided with identical designations, wherever appropriate.

In accordance with various embodiments, one aspect of the disclosure can be considered the fact that, by processing a surface using a particle beam two or multiple times at respectively different angles between the particle beam and the surface, the transition from an initial topology of the surface to a target topology of the surface can be achieved. The size of the area of incidence of the particle beam on the surface is settable using the different angles. In each processing operation, a different size of the area of incidence of the particle beam on the surface can be used to set the spatial resolution of the respective processing operation. In this way, processing can be adapted dynamically to the circumstances of the topology of the surface. For example, unevennesses or structures can be processed with different spatial resolutions that have been adapted to the size scales of the unevennesses or structures. Since for setting the spatial resolution only the angle is changed, but for example the particle beam generation is not changed, the (total) method duration can be decreased, because for example after changing the particle beam generation, a particle beam may take some time until it once again operates in a stable fashion.

FIG. 1 schematically illustrates an arrangement 100 for a method for processing a surface 110 using a particle beam 106.

The arrangement 100 may include a chamber 102. A particle beam source 104, which can emit the particle beam 106, may be arranged in the chamber 102. The particle beam 106 may be incident in an area of incidence 108 on the surface 110. The surface 110 may here be the surface of a substrate 112. The substrate 112 may be attached to a holder 114. The arrangement 100 may include at least one pump system 116, a cooling system 118, and a particle beam controller 120. The arrangement 100 may furthermore include a particle beam positioning system 122, a surface positioning system 124, and at least one processor 126.

As is schematically illustrated, the holder 114, the pump system 116, the cooling system 118, the particle beam controller 120, the particle beam positioning system 122, the surface positioning system 124, and the at least one processor 126 may be connected to the chamber 102, for example can be coupled electrically and/or mechanically to components in the chamber 102. The different components of the arrangement 100 may include different connections, for example electrical couplings, to one another (not illustrated). The different components of the arrangement 100 may be located in or at least partially in the chamber 102. The processor 126 may be connected, for example electrically coupled, to each of the or at least to some components of the arrangement 100 (components, which may be situated both in the chamber 102 and outside) to control, regulate, monitor them and/or check their status. In each case one component of the arrangement 100 may also be set up to control, regulate, monitor one or more other components, and/or to check the status thereof. The arrangement 100 may include one or more additional components (not illustrated in FIG. 1), such as one or more power controllers, power distributions (power distribution networks), resource controllers, resource storage means, resource distributions (wherein examples of resources may be water for cooling and gas for the particle beam generation) and network connections for controlling or monitoring for example the processor 126 using a further processor.

The chamber 102 may be set up to produce and maintain, for example using the pump system 116, which may include at least one pump, a vacuum in the chamber 102, for example a rough vacuum, a fine vacuum, a high vacuum or an ultra-high vacuum. For example, a vacuum may be produced and/or maintained that allows at least a desired part of the particle beam 106 to reach the surface 110. The pump system 116 may also be used to at least partially fill the chamber 102 with a gas. For example, it is possible for a gas to be guided into the chamber 102 by a majority of the residual atmosphere in the case of a vacuum consisting of this gas. For example, such a gas can be nitrogen or a noble gas such as argon, which is not reactive for example with respect to the surface 110 and the surface processing with the particle beam 106. For example, it is possible in this way to at least partially prevent oxygen from oxidizing the surface 110, in particular in the case of a temperature development during a surface processing operation. The pump system 116 may additionally be set up to vent the chamber 102, such that the chamber 102 can be opened and the substrate 112 can be removed from the chamber 102.

The cooling system 118 may be set up, for example divided over a plurality of cooling systems, to cool the arrangement 100. For example, the particle beam source 104, the substrate 112 or the surface 110 thereof, and the chamber 102 may be set up such that they can be cooled using the cooling system 118. Due to temperature development during the generation of the particle beam 106 and/or during the processing of the surface 110, for example, cooling may be necessary to protect the respective materials, or may lead to less maintenance complexity.

The particle beam controller 120 may be set up to control and/or regulate the particle beam 106 and/or the beam characteristic thereof, for example a particle beam current density distribution. The particle beam controller 120 can be mounted for example within or outside or partially within or partially outside the chamber 102. The particle beam controller 120 may for example also be set up to control the generation of the particle beam 106. Parameters that are to be controlled and/or regulated can be, for example, the energy supply to a plasma in the particle beam source 104, an acceleration voltage for accelerating particles from a plasma, a diameter of the particle beam 106, for example the diameter of the particle beam 106 on the surface 110, a particle flux, a particle density and a particle beam current density distribution, and also one or more parameters for the gas supply of the particle beam source 104, for example the flow rate.

The particle beam positioning system 122 and/or the surface positioning system 124 may be set up such that the particle beam 106, or the area of incidence 108 thereof, may be guided, for example scanned, over the surface 110 such that the particle beam 106 can reach every region of the surface 110. For example, the particle beam 106 can be guided across the surface 110 on the basis of an (ascertained) plan of procedure. Furthermore, the particle beam positioning system 122 and/or the surface positioning system 124 can be set up to set and/or change the angle between the particle beam 106 and the surface 110, for example using the holder 114 or a holder of the particle beam source 104 (not illustrated).

The processor 126, for example also plurality of processors, which may be coupled to one another, may be present as part of one (or more) computers. For example, the processor 126 may be set up to monitor, regulate and/or control the pump system 116, the cooling system 118, the particle beam controller 120, the particle beam positioning system 122 and/or the surface positioning system 124.

The processor 126 may be set up to simulate, for example using one or more simulations, analytical and/or numerical calculations, a surface processing operation of the surface 110 with the particle beam 106 and to monitor, regulate and/or control the surface processing by way of the simulation.

FIG. 2 schematically illustrates an embodiment of a method for processing a surface using a particle beam.

A method for processing a surface may include measuring the surface, designated with the reference sign 202.

The surface may be the surface of a substrate, for example. For example, the substrate can be an optical structural element, such as a mirror or lens. For example, the substrate may also be a semiconductor material or a dielectric layer or for example a structural element from chip technology or chip production technology, or a sensor.

Measuring the surface to ascertain the initial topology of the surface may be effected for example optically, for example using an interferometer. For example, an interferometer may be used to measure a production-related surface unevenness of a substrate with a precision on a nanometre size scale.

A desired target topology of a surface may for example relate to the surface being as planar as possible, such as for example in the case of optical elements such as a mirror or a lens, providing a surface with a desired pattern, or removing the material from the surface, for example to obtain a desired thickness of the substrate or to expose at least partially a layer under a layer on the substrate. In addition, a desired layer thickness or structure of one or more layers on a substrate can also be obtained. For example, structural elements such as piezoelectric high-frequency filters or Bragg mirrors can be realized, or such structural elements can be adapted, for example to a frequency of an electromagnetic wave.

After measuring the surface of the substrate, the substrate may be attached to a holder, for example by way of clamping, and subsequently be inserted into a particle beam arrangement. A particle beam arrangement may be for example an apparatus for ion beam processing (or an apparatus for electron beam processing). For example, an ion beam source may be set up to generate a plasma in a vacuum, wherein ions can be accelerated out of the plasma using one or more electrical fields. The thus accelerated ions can form an ion beam which can be focused for example using electrical fields, for example by way of an electrical voltage applied to electrical conductors.

Designated with the reference sign 204, a simulation can be effected for example using one or more processors and corresponding software.

A simulation may be effected for example by way of first obtaining the difference between an initial topology and a desired target topology. This difference may indicate, for example in the form of a function with two parameters (for example an “x”-coordinate and a “y”-coordinate), an amount of material that is to be removed locally, for example a layer thickness. This difference, for example in the form of such a function, may be transformed using a mathematical Fourier transform. The Fourier transform may be used to ascertain a surface waviness.

In illustrative terms, a surface waviness or a mathematical surface waviness function can be understood to mean that comparatively “large” structures, for example extending over the entire surface, can be represented as comparatively low frequencies of the surface waviness, wherein comparatively “small”, local structures can be represented as comparatively large frequencies of the surface waviness.

After ascertainment of the surface waviness, a calculation/simulation can be effected. For example, using an algorithm, for example what is known as a “Gold” deconvolution algorithm, as is used for example in image processing, in the case of a known ion beam diameter and a known ion beam characteristic (for example in the case of a known current density distribution), it is possible to calculate/simulate how the ion beam can be guided across the surface to obtain a desired target topology of the surface. For example, a movement profile/plan of procedure for the ion beam can be established such that the ion beam may be moved across the surface with changing speeds with a corresponding area of incidence on the surface. Such a simulation can also calculate (at least an estimated) processing duration.

Such a simulation may be effected such that two or more processing operations with different areas of incidence are simulated, for example with areas of incidence which differ in terms of the geometric size and the ion current density distribution on the surface. A simulated/calculated topology of the surface after a preceding processing operation can here be used as the basis or a parameter, i.e., as a simulated/calculated further initial topology, for a subsequent simulated/calculated processing operation. Alternatively, a calculation/simulation can also be effected such that multiple processing operations simultaneously in a process are simulated.

Illustratively, such a simulation, possibly in multiple parts, can divide the processing into a plurality of partial processing operations. For example, the ascertainment of the surface waviness can show that the surface includes both comparatively low frequencies (or frequency ranges) and comparatively high frequencies (or frequency ranges) at the same time. Division can also be effected into more than two frequency ranges. For example, the size of one area of incidence of the ion beam can be suitable for processing one ascertained frequency range, and a different size of another area of incidence of the ion beam can be suitable for processing a different ascertained frequency range. For example, the simulation may also be used to ascertain suitable areas of incidence (or angles), for example in dependence on the surface waviness of the surface to be processed. Furthermore, one or more areas of incidence can be defined previously, and one or more further areas of incidence can be ascertained using the simulation in a manner adapted to the topology of the surface and to the areas of incidence which were defined previously. On the basis of the one or more simulations, a movement profile/plan of procedure for the ion beam and angle of the ion beam with respect to the surface can be ascertained and established.

Designated with the reference sign 206, the multiple ion beam processing operations can subsequently be performed successively, for example using the ascertained plurality of movement profiles/plans of procedure and angles. The different areas of incidence of the ion beam can be realized in that, during each processing operation, the ion beam has a different angle with respect to the surface. For example, the area of incidence of an ion beam on a surface at one angle can be circular, and can be elliptical at another angle.

In the case of processing the surface by way of different areas of incidence, which are set using different angles between the surface and the ion beam, for example the fact that the local ion density/ion current density distribution that is incident on the surface in an area of incidence changes can be incorporated in a simulation/calculation. In addition, the processing itself can differ, because in the case of surface materials that are processed using a particle beam at different angles, a different removal rate depending on the angle is obtained; for example, the material to be processed can be crystalline and the crystal can have a preferential direction, such that an angle-dependent removal rate can be determined.

Subsequently, the substrate can be taken out of the ion beam apparatus, for example, and the surface can be measured again to ascertain the result of the method. Deviations in the result with respect to the simulated result can serve as parameters for improving the simulation of further processing operations.

FIG. 3 schematically illustrates a further embodiment of a method 300 for processing a surface using a particle beam.

A method for processing a surface having an initial topology using a particle beam can include the processing of the surface using a particle beam at a first angle between particle beam and surface, designated with the reference sign 302.

Subsequently, as described in 304, the same surface can be processed at least a second time with the particle beam, wherein in the case of each processing operation a different angle between particle beam and surface is set, with the result that after the at least two processing operations the difference between the initial topology of the surface and a target topology of the surface lies below a threshold value.

FIG. 4 schematically illustrates a further embodiment of a method 400 for processing a surface using a particle beam.

A method for processing a surface having an initial topology using a particle beam can include performing a first processing operation of the surface using the particle beam, designated with the reference sign 402, wherein the particle beam is incident on the surface at an angle with respect to the surface.

The method can further include simulating the topography of the surface after the first processing operation, designated with the reference sign 404.

The method may furthermore include performing at least one further processing operation proceeding from the simulated topology of the surface after the first processing operation, designated with the reference sign 406.

Each processing operation may be performed with in each case a different angle of the particle beam with respect to the surface, with the result that, after the at least one further processing operation, the difference between the initial topology of the surface and the target topology of the surface lies below a threshold value.

FIG. 5A schematically illustrates an embodiment of a processing operation of a surface 508 at an angle 510.

A particle beam source 502 may emit a particle beam 504. The particle beam 504 may have an axis 506, wherein the axis 506 is here understood to constitute a model/auxiliary line. The particle beam 504 may be incident on the surface, and act on the surface, at a first angle 510, for example an angle between the axis 506 of the particle beam 504 and the surface 508.

FIG. 5B shows a modification of FIG. 5A, wherein the particle beam 504 is incident on the surface 508 at a second angle 512, which differs from the first angle 510.

FIG. 5C schematically illustrates the surface 508 of FIG. 5A from a different perspective.

In this perspective, the area of incidence of the particle beam 514 is shown. Due to the angle 510, the area of incidence 514 is elliptically distorted with respect to another angle setting, for example a second angle 512. This may for example also mean that a particle beam current density distribution of the particle beam 504 on the surface 508 can be elliptically distorted with respect to another angle setting.

FIG. 5D schematically illustrates the surface 508 of FIG. 5B from a different perspective.

Similarly to FIG. 5C, the area of incidence 516 of the particle beam 504 on the surface 508 is illustrated in this perspective. In this example, the second angle 512 is 90° and the area of incidence 516 is circular.

For example, the first angle 510 may be able to be transitioned smoothly into the second angle 512. An angle may be able to be transitioned for example using a translation and rotation of the particle beam source 502 and/or a translation and/or rotation of the surface 508.

FIG. 6 schematically illustrates a diagram of the volume etch rate as a function of the angle of incidence.

The removal rate can differ with the material to be processed and the angle between particle beam and the surface of the material. Illustrated are, by way of example, for two materials, the respective dependences of the volume rate (or volume removal rate or volume etch rate) on the angle of incidence (angle between particle beam and surface of the material to be processed). The measurement curve 602 represents the dependence of the volume rate on the angle of incidence for aluminium oxide, and the measurement curve 604 represents the dependence of the volume rate on the angle of incidence for permalloy (NiFe alloy).

Illustrated for aluminium oxide for example is that the removal rate for an angle of incidence can have a local maximum 606. Furthermore, at a point 608, the different materials may have the same removal rate at the same angle of incidence.

The removal rate for a material at an angle may depend on a plurality of parameters and properties. Examples are the crystal structure and crystal orientation of the material or whether the material for example is amorphous, the temperature of the material and the suitability/interaction of the particles of the particle beam for/with the material.

In this example, the volume rate for aluminium oxide 602 has a local maximum 606 at an angle of incidence of between approximately 30° and 40°. As described above, the attainable spatial resolution, however, can be maximum, or have a local maximum, at a different angle of incidence (for example 0°). As a result, selecting an angle, or selecting a plurality of angles, can in each case and overall represent a balance between attainable spatial resolution and attainable removal rate (and consequently also total process time). For example, the spatial resolution at normal incidence can be relatively high or even maximum and the removal rate can be relatively low, and at another angle, the spatial resolution can be relatively low but the removal rate be relatively high or even maximum. Furthermore, in the case of such balance, it is also important whether the material consists of different substances/sub-materials, which have different dependencies on removal rate over angle of incidence.

1. A method for processing a surface, having an initial topology, using a particle beam, the method comprising:
processing the surface using the particle beam at a first angle of the particle beam with respect to the surface in accordance with a target topology of the surface; and
subsequently processing the surface using the particle beam at a second angle of the particle beam with respect to the surface in accordance with the target topology of the surface, wherein the second angle differs from the first angle,
wherein the particle current density and/or the particle current flow of the particle beam during the processing operations of the surface are substantially the same, and/or wherein only the angle of the particle beam with respect to the surface is changed, wherein further parameters of the particle beam, of the particle beam characteristic and/or of the particle beam generation are kept substantially constant or only exhibit deviations below a tolerance value.

2. A method for processing a surface, having an initial topology, using a particle beam, the method comprising:
processing the surface using the particle beam, wherein the particle beam is incident on the surface at a first angle with respect to the surface in accordance with a target topology of the surface;
simulating the processing of the topology of the surface at a second angle after processing the topology of the surface at the first angle; and
subsequently processing starting from the simulated topology of the surface using the particle beam, wherein the particle beam is incident on the surface at a second angle with respect to the surface in accordance with a target topology of the surface, wherein the second angle differs from the first angle,
wherein the particle current density and/or the particle current flow of the particle beam during the processing operations of the surface are substantially the same, and/or wherein only the angle of the particle beam with respect to the surface is changed, wherein further parameters of the particle beam, of the particle beam characteristic and/or of the particle beam generation are kept substantially constant or only exhibit deviations below a tolerance value.

3. The method according to claim 2,
wherein simulating the topology of the surface is performed before and/or during the processing operation at the first angle.

4. The method according to claim 1, further comprising:
simulating successively performed processing operations on the surface with the particle beam at respectively different angles of the particle beam with respect to the surface, wherein at least one simulation is used to ascertain at least the respectively different angles for the successively performed processing.

5. The method according to claim 1,
wherein the first angle and/or the second angle of the particle beam with respect to the surface is/are infinitely settable.

6. The method according to claim 1,
wherein the first angle and/or the second angle of the particle beam with respect to the surface is/are set by way of positioning the particle beam and/or by way of positioning the surface.

7. The method according to claim 1,
wherein an instantaneous topology of the surface is measured only before and/or after the two processing operations of the surface.

8. The method according to claim 1,
wherein the surface is processed in a chamber having a pressure which is lower than the air pressure, and the chamber is vented and/or opened only before and after both processing operations of the surface.

9. The method according to claim 1, further comprising:
regulating and/or controlling the temperature of the surface in dependence on the angle of the particle beam with respect to the surface.

10. The method according to claim 2, further comprising:
simulating successively performed processing operations on the surface with the particle beam at respectively different angles of the particle beam with respect to the surface, wherein at least one simulation is used to ascertain at least the respectively different angles for the successively performed processing.

11. The method according to claim 2,
wherein the first angle and/or the second angle of the particle beam with respect to the surface is/are infinitely settable.

12. The method according to claim 2,
wherein the first angle and/or the second angle of the particle beam with respect to the surface is/are set by way of positioning the particle beam and/or by way of positioning the surface.

13. The method according to claim 2,
wherein an instantaneous topology of the surface is measured only before and/or after the two processing operations of the surface.

14. The method according to claim 2,
wherein the surface is processed in a chamber having a pressure which is lower than the air pressure, and the chamber is vented and/or opened only before and after both processing operations of the surface.

15. The method according to claim 2, further comprising:
regulating and/or controlling the temperature of the surface in dependence on the angle of the particle beam with respect to the surface.

16. The method according to claim 3, further comprising:
simulating successively performed processing operations on the surface with the particle beam at respectively different angles of the particle beam with respect to the surface, wherein at least one simulation is used to ascertain at least the respectively different angles for the successively performed processing.

17. The method according to claim 3,
wherein the first angle and/or the second angle of the particle beam with respect to the surface is/are infinitely settable.

18. The method according to claim 3,
wherein the first angle and/or the second angle of the particle beam with respect to the surface is/are set by way of positioning the particle beam and/or by way of positioning the surface.

19. The method according to claim 3,
wherein an instantaneous topology of the surface is measured only before and/or after the two processing operations of the surface.

20. The method according to claim 3,
wherein the surface is processed in a chamber having a pressure which is lower than the air pressure, and the chamber is vented and/or opened only before and after both processing operations of the surface.

21. The method according to claim 3, further comprising:
regulating and/or controlling the temperature of the surface in dependence on the angle of the particle beam with respect to the surface.
